(19) United States
(12) Patent Application Publication
(10) Pub. No.: US 2012/0204941 A1
(43) Pub. Date: Aug. 16, 2012

(54) ALLOTROPIC CHANGES IN SI AND USE IN FABRICATING MATERIALS FOR SOLAR CELLS

(76) Inventors: James T. Cargo, Bethlehem, PA (US); Frank A. Baiocchi, Allentown, PA (US); John M. DeLucca, Wayne, PA (US)

(21) Appl. No.: 13/027,349

(22) Filed: Feb. 15, 2011

(51) Int. Cl. H01L 31/06; H01L 21/268; H01L 29/04

(52) U.S. Cl. 136/255; 257/51; 438/96; 257/E21.347; 257/E29.003

(57) ABSTRACT

A method provides forming a photovoltaic (PV) cell. The PV cell may be, e.g. a heterojunction with intrinsic thin layer (HIT) cell. The method includes forming a crystalline semiconductor layer over a substrate. The crystalline semiconductor layer is heated above a melting temperature of the semiconductor. A portion of the crystalline semiconductor layer is thereby converted to a quenched amorphous semiconductor layer.

### TECHNICAL FIELD

This application is directed, in general, to photovoltaic cells, and methods of making such cells.

### BACKGROUND

The development of renewable energy sources is expected to become increasingly urgent as fossil energy sources dwindle and concern over CO₂ emissions increases. Solar, or photovoltaic cells, have become increasingly efficient as researchers make incremental improvements, and increasingly cost effective as the cost of energy from other sources rises. However, the efficiency of some (e.g. silicon homojunction) solar cells is only in the range of 5%. Heterojunction photovoltaic cells may have a greater efficiency, but may benefit from further improvement of methods of forming these cells before being widely adopted.

### SUMMARY

One aspect provides a method of forming a photovoltaic cell. The method includes providing a substrate. A crystalline semiconductor layer is formed thereover. The crystalline semiconductor layer is heated above a melting temperature of the semiconductor. A portion of the crystalline semiconductor layer is thereby converted to a quenched amorphous semiconductor layer.

Another embodiment provides a photovoltaic cell. The cell includes a substrate. An amorphous semiconductor layer is located over the substrate. The amorphous semiconductor layer is formed by heating a surface of a crystalline semiconductor layer above a melting point of the semiconductor. The heating converts at least a portion of the crystalline semiconductor layer to an amorphous allotrope of the semiconductor.

Yet another embodiment provides a photovoltaic cell. The photovoltaic cell includes a layer of a crystalline semiconductor material over a substrate. The crystalline semiconductor material has a first conductivity type. A quenched amorphous layer of the semiconductor material is located over the substrate. The quenched amorphous layer has a second different conductivity type. The quenched amorphous layer comprises no more than about 0.1 at. % hydrogen.

Another embodiment provides a semiconductor wafer. The wafer includes a crystalline semiconductor substrate with an amorphous semiconductor layer located thereover. The amorphous semiconductor layer is formed by heating a surface of a crystalline semiconductor layer above a melting point of the semiconductor. The heating converts at least a portion of the crystalline semiconductor layer to an amorphous allotrope of the semiconductor.

### BRIEF DESCRIPTION

Various features of the accompanying drawings may not be drawn to scale. In some cases the dimensions of various features may be arbitrarily increased or reduced for clarity of discussion. No limitation on the thickness of any material layers is implied by relative thicknesses of features as illustrated. Reference is now made to the following descriptions taken in conjunction with the accompanying drawings, in which:

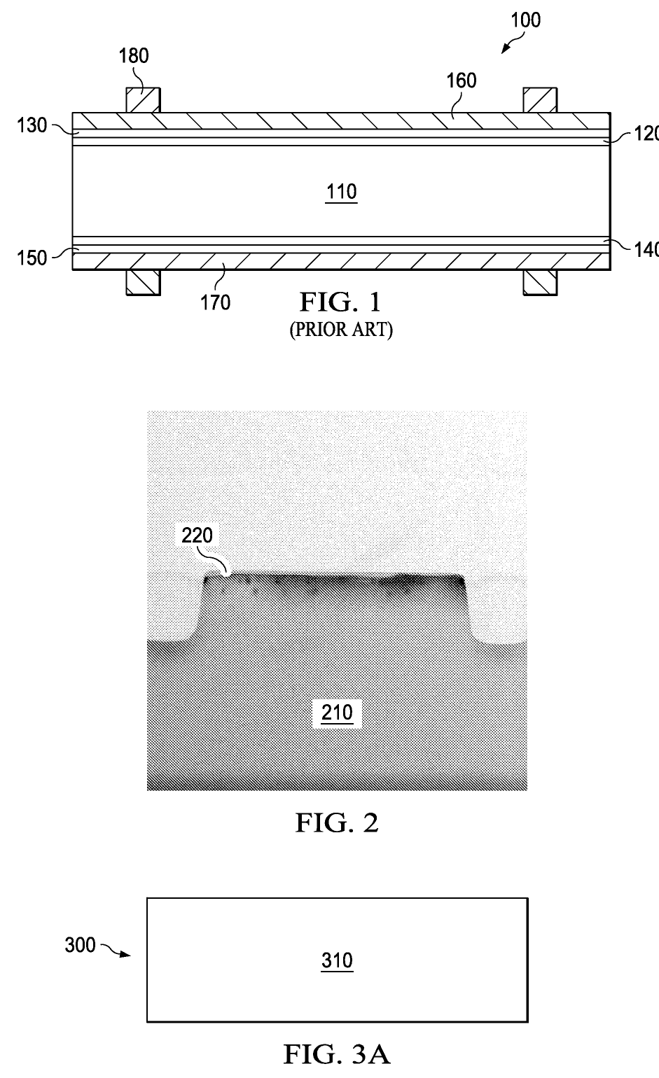

FIG. 1 illustrates a prior art HIT photovoltaic cell;

FIG. 2 illustrates a sectional view of a crystalline silicon substrate after illuminating with laser light, thereby forming a quenched amorphous layer on the crystalline substrate;

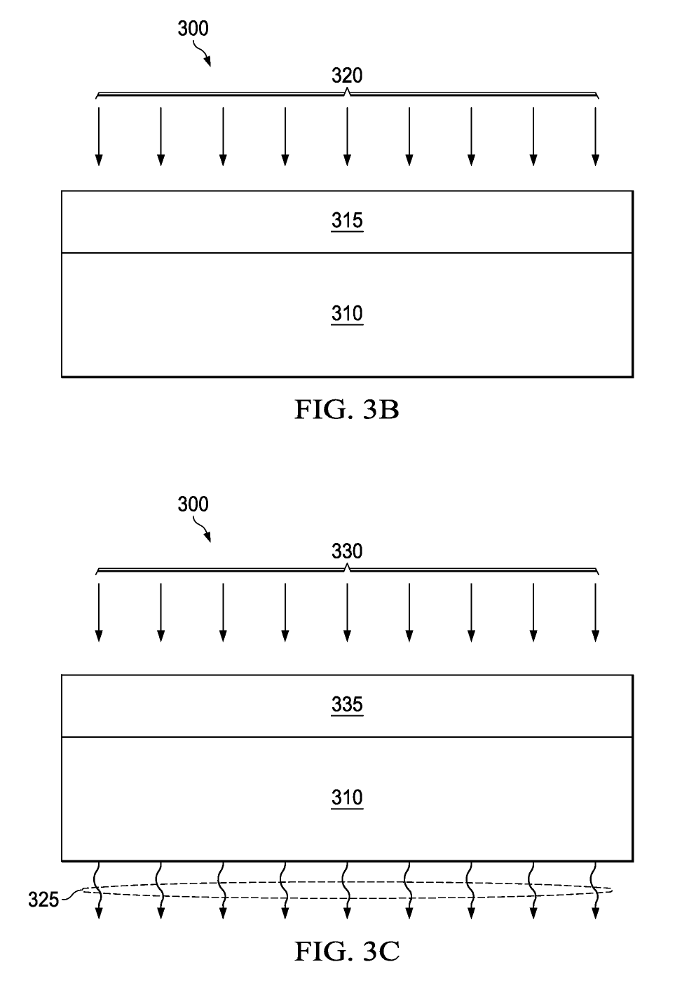

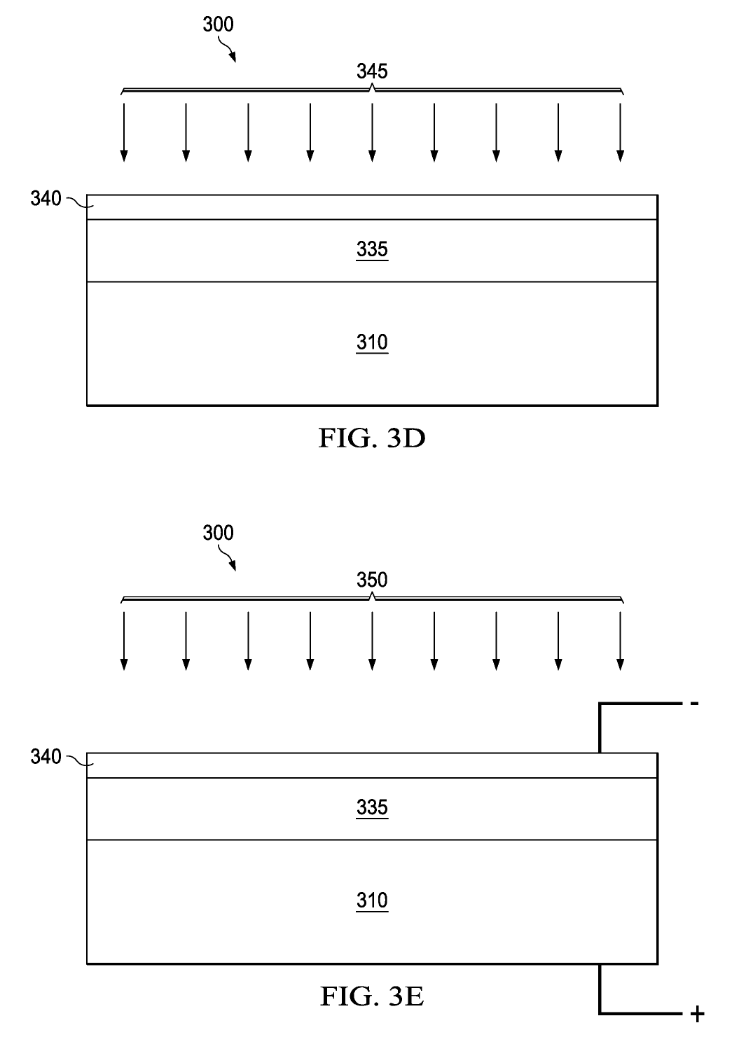

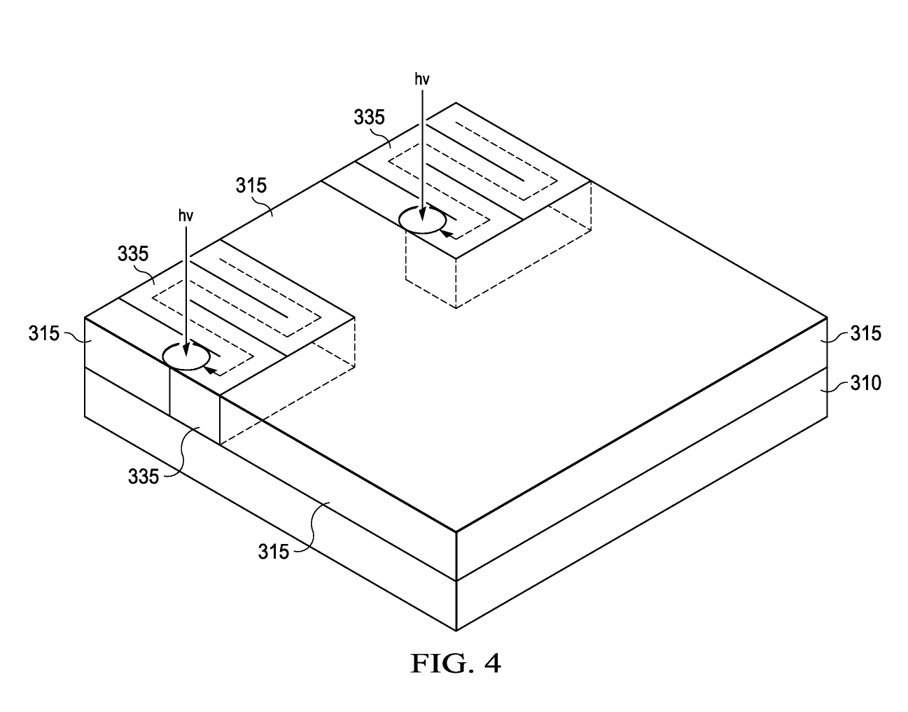

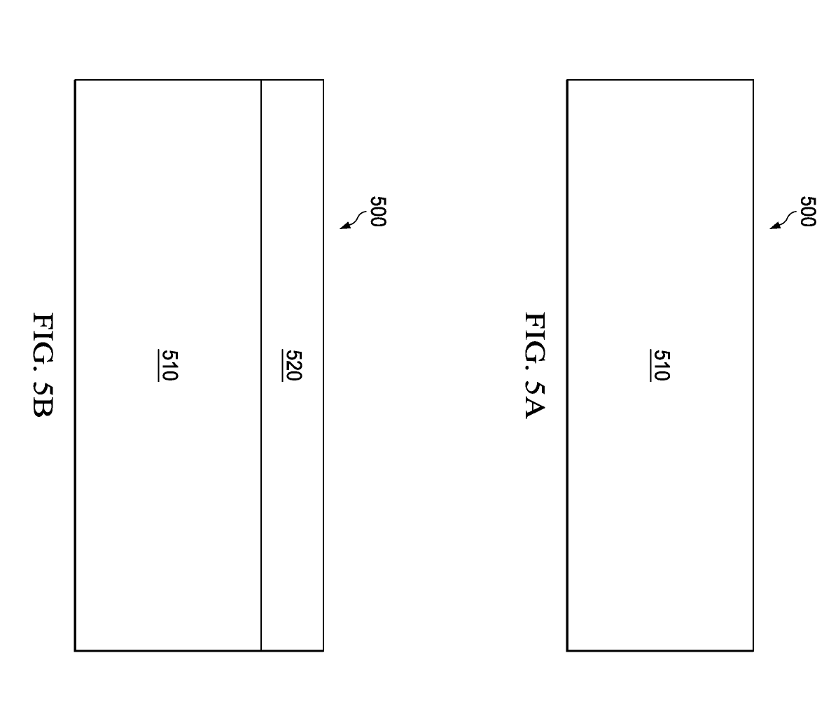

FIGS. 3A-3E illustrate a method of the disclosure of forming a photovoltaic cell having a heterojunction formed between a doped crystalline semiconductor and an oppositely doped quenched amorphous semiconductor;

FIG. 4 illustrates rastering of multiple illumination spots over a surface of a crystalline semiconductor, thereby converting a portion of the semiconductor from a crystalline allotrope to a quenched amorphous allotrope; and

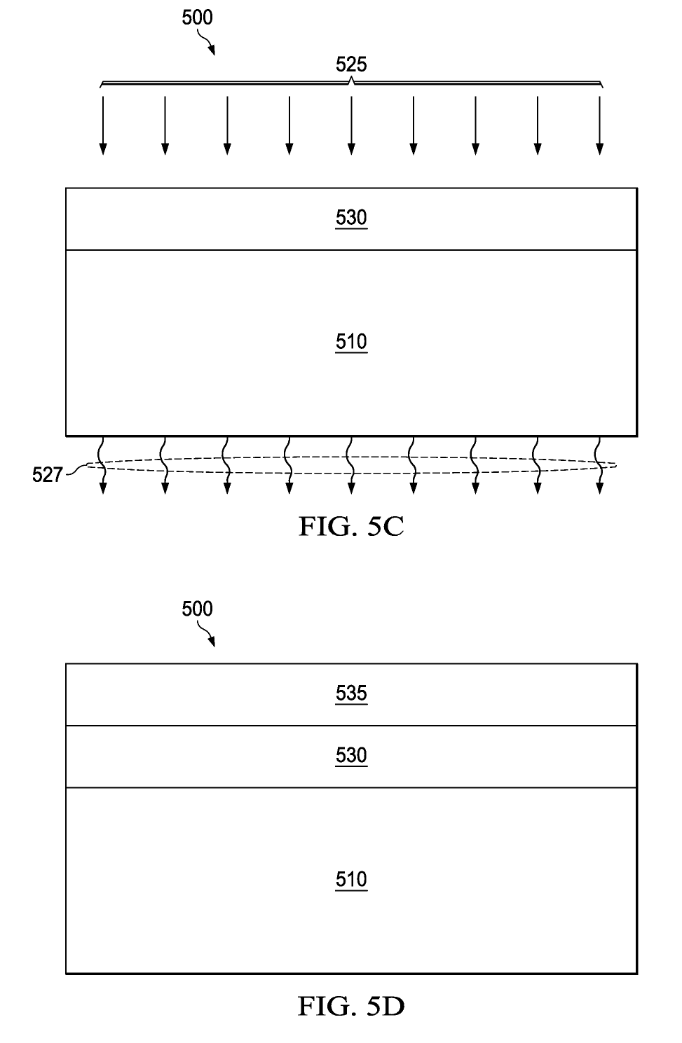

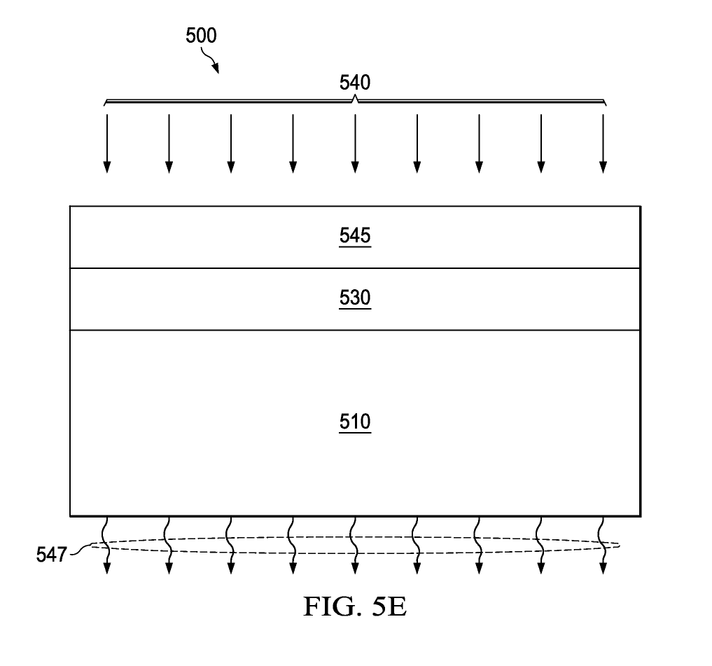

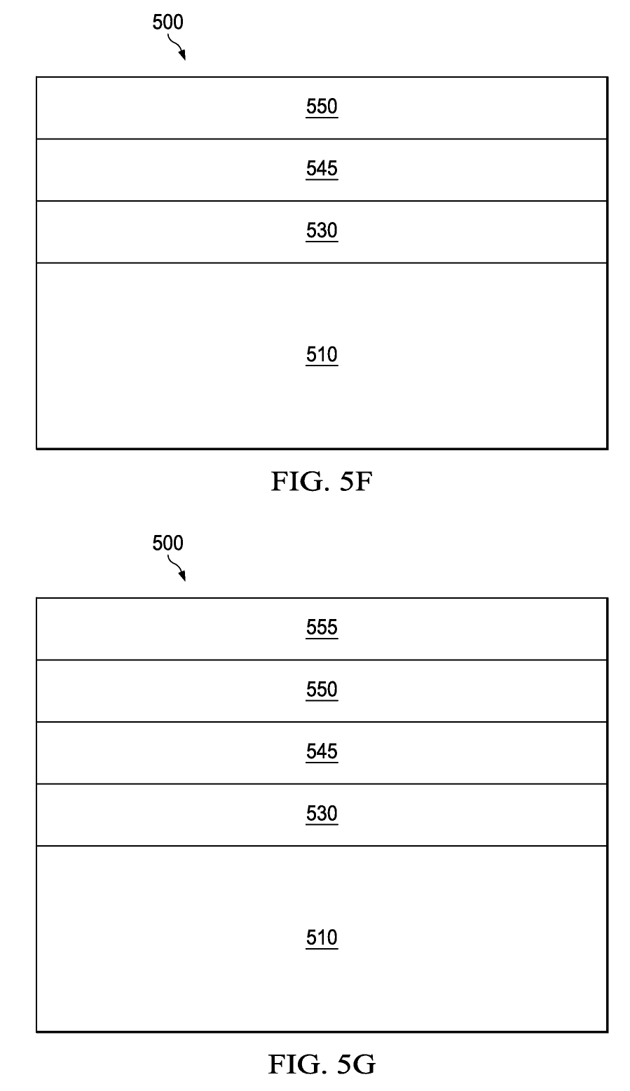

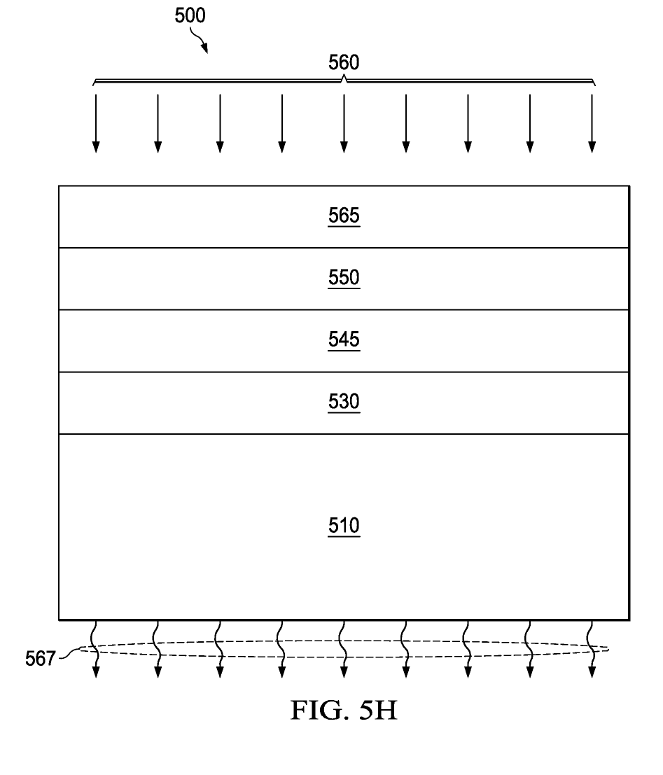

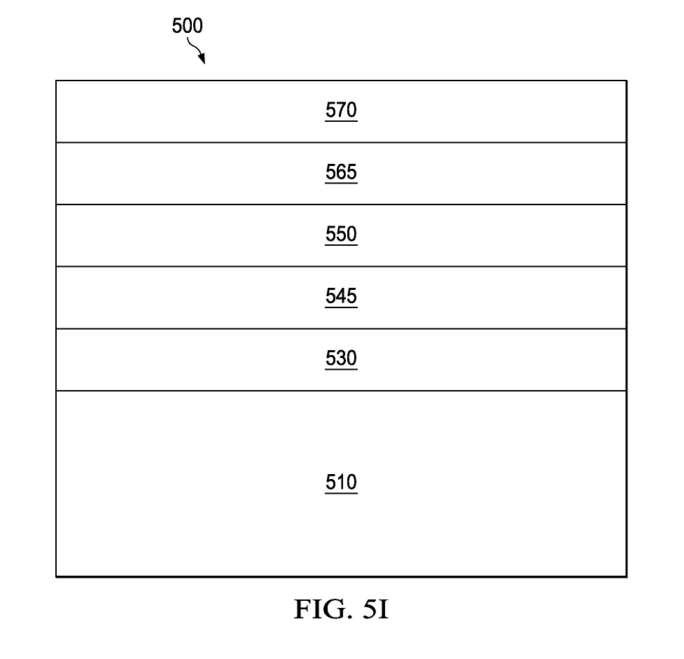

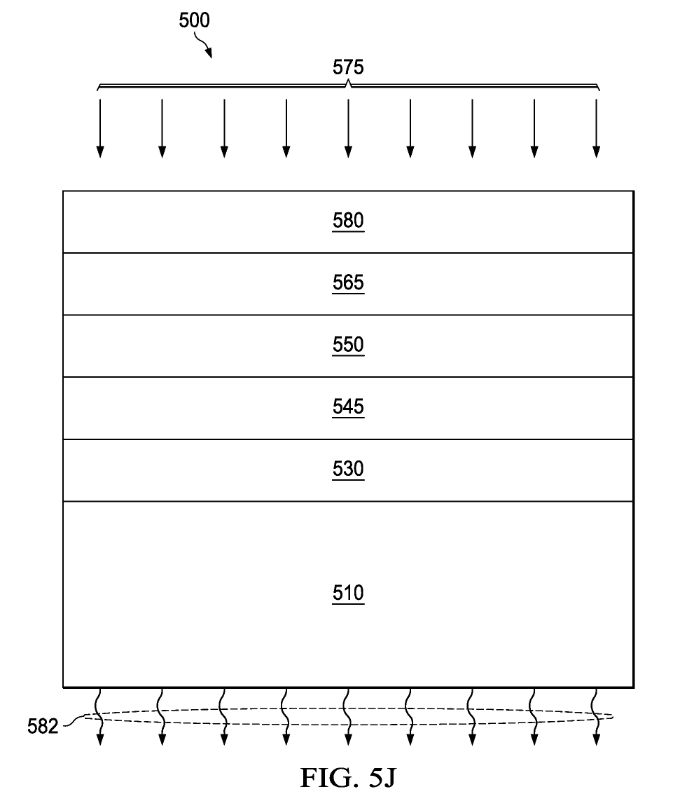

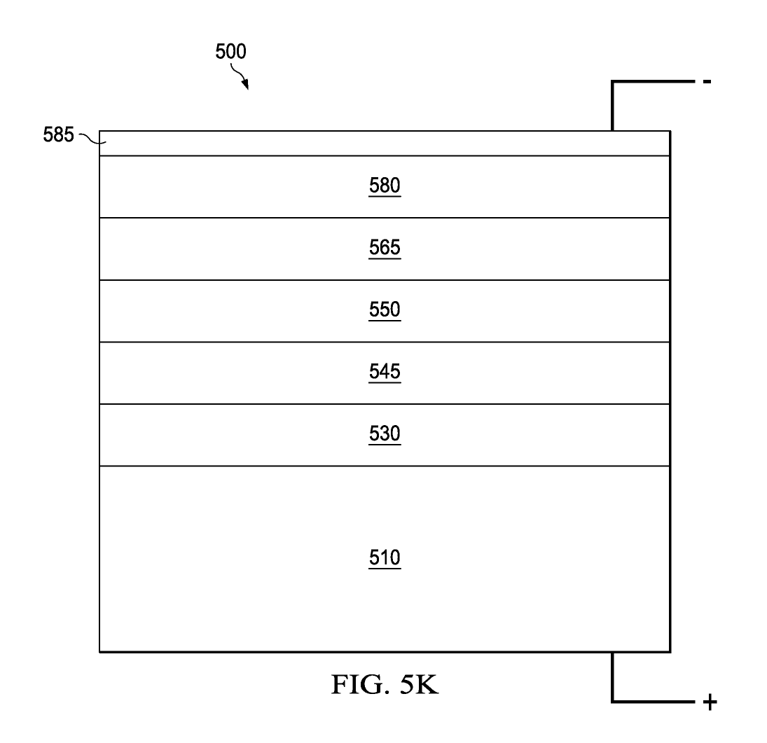

FIGS. 5A-5K illustrate a method of the disclosure of forming an HIT photovoltaic cell.

### DETAILED DESCRIPTION

One type of heterojunction photovoltaic (PV) cell that has shown promise for greater efficiency is the “heterojunction with intrinsic thin layer” (HIT) cell. Some such cells currently may have an efficiency of about 20%. However, they are more expensive to produce than simpler PV cell types. Forming HIT cells typically includes multiple passes through an amorphous silicon deposition chamber. These steps add considerable cost to the HIT cell, thus increasing the initial investment required to install a system of such cells, and increasing the payback period of the system. Moreover, amorphous silicon formed by such conventional methods typically includes hydrogen as an impurity. The hydrogen concentration often changes over time, rendering the electrical properties of the cell unstable. This instability may reduce the useful life of a PV cell, thereby increasing the operating cost over the lifetime of the cell.

This disclosure provides improved methods of forming a PV cell, and improved PV cells. The improvements are based on the recognition on the part of the inventors that an amorphous semiconductor layer may be formed on a crystalline semiconductor layer by illuminating the crystalline semiconductor layer with high-intensity light to cause localized melting, and quenching the molten semiconductor. Amorphous semiconductor layers formed using methods of the disclosure in some cases may have greater purity than such layers formed by conventional methods, and in some cases may be formed less expensively than those formed by conventional methods. Thus, electrical stability may be improved and/or the cost of producing the cell may be reduced. Even in embodiments in which the semiconductor layer impurities are not reduced relative to conventional PV cells, PV cells of the disclosure are expected to benefit from improved control of the thickness of amorphous semiconductor layers. Such control is expected to result in superior yield and/or operating characteristics of PV cells formed by the disclosed methods.

The disclosure includes references to various forms of semiconductor materials. While the discussion is not limited to a particular semiconductor material, for convenience the discussion may refer to silicon without limitation. The following convention is followed throughout with respect to various forms of silicon:

a-Si: designates the amorphous morphology allotrope of silicon;

c-Si: designates the single-crystalline morphology allotrope of silicon; and

p-Si: designates the polycrystalline morphology allotrope of silicon.

Herein, allotrope refers to a form of an elemental or compound semiconductor determined by an arrangement of chemical bonds between atoms of the semiconductor. More specifically, crystalline and polycrystalline materials are one allotropic form of silicon while amorphous material is a second different allotropic form. Herein, different allotropes of a semiconductor also have a different morphology. Single crystal silicon and polycrystalline silicon are of the same allotrope, but have differing morphologies.

Herein a conductivity type of a semiconductor material refers to conductivity that predominantly occurs by electron conduction or by hole conduction. Thus, an n-type semiconductor has a first conductivity type, and a p-type semiconductor has a second different conductivity type. For the purposes of the disclosure, an intrinsic semiconductor, e.g. having about a same concentration of holes and electrons, has a third conductivity type that is different from the n-type and p-type semiconductors.

FIG. 1 illustrates a typical prior art HIT PV cell 100. An upper side, as viewed in FIG. 1, of an n-type c-Si region 110 supports a first intrinsic a-Si layer 120 and a p-type a-Si layer 130. A lower side of the c-Si region 110 supports a second intrinsic a-Si layer 140 and an n-type a-Si layer 150. A top transparent electrode 160 (e.g. indium-tin-oxide, or ITO) overlies the p-type a-Si layer 130, and a bottom transparent electrode 170 overlies the n-type a-Si layer 150. Grid electrodes 180 provide an electrical connection to the top and bottom electrodes 160, 170 to tap the power produced by the cell 100 when the cell 100 is illuminated.

The HIT cell 100 represents a significant advancement in photovoltaic energy production. However, the high cost of production renders the cell 100 uneconomical for many applications. The high cost is due in part to the cost of forming the amorphous layers 120, 130, 140, 150.

Typically, an amorphous semiconductor layer, such as silicon, is deposited in a chemical-vapor-deposition (CVD) process. For example, a-Si may be formed in a conventional process using a silane (SiH₄) feedstock. The silane may be doped in situ to result in an n-type or p-type a-Si layer if desired, such as for the amorphous layers 130, 150. However, each amorphous layer 120, 130, 140, 150 typically must be formed in a separate process. Thus, for example, the cell 100 may require four separate processes to produce the amorphous layers 120, 130, 140, 150. Furthermore, because amorphous semiconductor layers are typically formed using a hydrogen-containing compound of the semiconductor element (e.g., silane, germane), the amorphous layers 120, 130, 140, 150 may contain significant amounts of residual hydrogen. In some cases, for instance, a-Si may contain as much as about 30 at. % hydrogen. While hydrogen may be beneficial in some respects, loss of hydrogen over time is generally associated with unstable electrical characteristics.

PCT Application No. PCT/US2008/076976 (the '976 Application), incorporated herein by reference in its entirety, discloses a method of employing a laser to convert a portion of a semiconductor substrate from a crystalline allotrope to an amorphous allotrope. FIG. 2, for example, illustrates in sectional view a crystalline silicon substrate 210 that has been illuminated by high-intensity light, in this case a laser. A quenched amorphous silicon layer 220 has been formed on the crystalline silicon substrate 210. The formation of the quenched amorphous silicon layer 220 by illumination may be significantly less expensive than conventional methods, such as CVD, of forming an amorphous semiconductor region on a crystalline region of the semiconductor. Moreover the formation may be done at room temperature, at ambient pressure and outside of a cleanroom environment.

The underlying crystalline silicon substrate 210 is typically substantially free of hydrogen, e.g. less than about 1 at. %. Because the quenched amorphous silicon layer 220 is formed from the silicon substrate 210, the quenched amorphous silicon layer 220 is also substantially free of hydrogen, e.g. having no greater than about 1 at. %, and in some embodiments has no more than about 0.1 at. % hydrogen. This hydrogen concentration represents a reduction of hydrogen concentration relative to CVD a-Si by a factor of at least 30-300. Thus the electronic properties of the quenched amorphous silicon layer 220 are expected to be more stable than the conventional amorphous layers used in PV cells.

Herein, a quenched amorphous semiconductor layer is a layer characterized by including little or no crystalline ordering. Some semiconductor processes, e.g. implantation, result in some disordering of the semiconductor lattice. Such disordering is typically minor compared to a quenched amorphous semiconductor. For instance, a semiconductor lattice damaged by implantation is expected to display an x-ray or electron diffraction pattern that is dominated by a peak associated with long-range ordering of the underlying lattice. While disorder may result in reduced intensity and broadening of the peak, the peak is expected to remain a dominant feature of the diffraction pattern. In contrast a quenched amorphous semiconductor is expected to be characterized by a diffraction pattern with little or no ordering peak.

The quenched amorphous semiconductor layer may also be distinguished from a damaged semiconductor lattice by transmission electron microscopy (TEM) analysis. High resolution TEM is capable of sufficiently resolving a crystalline semiconductor lattice that the underlying periodicity of the lattice is expected to be evident in a TEM cross section of an implanted semiconductor lattice, even when the implanted dopant concentration is high. On the contrary, a TEM cross section of a quenched amorphous semiconductor layer is expected to show little or no long-range ordering of the layer. While some small and isolated regions of local ordering are possible, such regions while remaining isolated are not inconsistent with characterization of the quenched amorphous layer as amorphous.

Turning to FIGS. 3A-3E, illustrated is a method of forming a heterojunction PV cell 300 that includes converting c-Si to a-Si. A heterojunction PV cell includes a junction between two dissimilar semiconducting materials. In the present context, an amorphous portion of a semiconductor material, e.g. silicon, in contact with a crystalline portion of the same semiconducting material is considered to form a heterojunction.

In FIG. 3A, the method provides a semiconductor substrate 310. As used herein, “provided” or “providing” include without limitation manufacturing the semiconductor substrate 310 in the local manufacturing environment in which subsequent steps in the method are performed, or 2) receiving the semiconductor substrate 310 from a source external to the local manufacturing environment.

The semiconductor substrate 310 may be any substrate suitable to mechanically support subsequent material layers, as described below, including for example a semiconductor wafer, glass, ceramic or quartz. In some embodiments, such as the illustrated embodiment, the substrate is a semiconductor layer that provides one terminal (e.g. a bottom terminal) of the PV cell 300. In other embodiments the bottom terminal of the PV cell 300 may be, e.g. a transparent conductor such as ITO or other similar material formed on an insulating substrate such as glass. In such embodiments electrical access to the bottom terminal (e.g. ITO) may be made, e.g., by etching an opening through the insulating substrate and electively stopping on the bottom terminal. In another example, an opening may be formed through any layers formed over the bottom terminal, again stopping on the bottom terminal. Those skilled in the pertinent art are familiar with methods of forming such openings. Once exposed, connection to the bottom terminal may be made in any conventional or novel manner.

In some embodiments the semiconductor substrate 310 is a p-type c-Si wafer, and is illustrated as such without limitation in FIGS. 3A-3E. Other substrate types may be used, including e.g. Ge, GaAs and InP. In some embodiments the semiconductor substrate 310 is heavily doped, e.g. with a dopant concentration of at least about 1 E 19 cm⁻³. While the semiconductor substrate 310 is not limited to being in wafer form, such a substrate provides a convenient platform for subsequent process steps that may be performed in semiconductor manufacturing tools.

FIG. 3B illustrates the PV cell 300 during formation of a doped semiconductor layer 315 on the semiconductor substrate 310. The doped semiconductor layer 315 may comprise an elemental or compound semiconductor, such as without limitation Si, Ge, GaAs, InP, CdTe, CdS, GaN, InN, Cu₂S, ZnTe, AlGaAs, InGaP, InGaN, CdZnTe and CuInGaSe. For convenience, the following discussion describes the PV cell 300 with reference to silicon without limitation thereto. In various embodiments the semiconductor substrate 310 and the doped semiconductor layer 315 comprise a same semiconductor material, e.g. both comprise Si.

The doped semiconductor layer 315 may be formed from the semiconductor substrate 310 by doping a surface portion of the semiconductor substrate 310 with an opposite-type dopant. For example, in the illustrated example of a p-type semiconductor substrate 310, the dopant may be n-type. A doping process 320, e.g. a phosphorous implant, may be used. The doping process may result in some disordering of the crystalline lattice within the doped semiconductor layer 315. However, any such disordering is not expected to disrupt the overall long range ordering associated with crystallinity.

The doping process 320 has an associated doping thickness. The doping thickness is the thickness of a surface layer of the semiconductor substrate 310 that includes about 90% of the implanted dopant. In various embodiments the doping process 320 is configured such that the doping thickness is about equal to the thickness of a melted surface layer formed in a subsequent process step, as described below. In various embodiments, the doping thickness is in a range from about 10 nm to about 500 nm, with a thickness of about 100 nm being preferred. A conventional implant process may be easily configured to achieve the desired thickness.

FIG. 3C illustrates the doped semiconductor layer 315 during exposure to an illumination process 330. The illumination process 330 may be high-intensity light from an illumination source. The illumination process 330 heats the doped semiconductor layer 315 above its melting point, causing at least portion of the doped semiconductor layer 315 to at least partially melt. The illumination process 330 may be configured to melt the doped semiconductor layer 315 to a depth about equal to the doping thickness described above, e.g. about 100 nm.

The semiconductor substrate 310 acts as a heat sink into which heat from the melted portion of the doped semiconductor layer 315 may diffuse. Because the semiconductor substrate 310 has a thickness that is typically much greater than the thickness of the doped semiconductor layer 315, e.g. by about 1000 times or more, and the thermal conductivity of the semiconductor substrate 310 is typically good, the heat from the melted portion is expected to rapidly diffuse into the semiconductor substrate 310. The melted portion rapidly cools, thereby quenching the melt, e.g. cooling the melt rapidly such that little or no crystalline material results, to form a doped quenched amorphous layer 335.

Because the quenched amorphous layer 335 is formed from material originally sourced by the semiconductor substrate 310, impurities within the amorphous doped layer 335 should be no greater than the impurities within the semiconductor substrate 310 as long as other sources of impurities are excluded. In particular, when the semiconductor substrate 310 is a conventional semiconductor wafer, the quenched amorphous layer 335 is expected to have a very low concentration of hydrogen, e.g. no greater than about 1 at. %, and in some cases no greater than about 0.1 at. %. This contrasts markedly with conventional methods of forming an amorphous semiconductor layer, e.g. a silane-based CVD process described earlier. The lower concentration of hydrogen in the quenched amorphous layer 335 is expected to significantly increase the operational stability of the PV cell 300 relative to a similar conventionally formed cell, thereby increasing its expected operational lifetime and reducing the cost of ownership of the PV cell 300.

In various embodiments the semiconductor substrate 310 is chilled via a chilling process 325 to increase the rate of heat flow from the melted portion of the doped semiconductor layer 315 to the semiconductor substrate 310. It is expected that the chilling will increasingly favor the production of amorphous silicon, rather than e.g. microcrystalline silicon, in the quenched amorphous layer 335.

Herein “chilled” means heat is removed from the semiconductor substrate 310 via an active means such as a refrigeration cycle or thermoelectric cooler. Chilling the semiconductor substrate 310 does not necessarily mean that the temperature of the semiconductor substrate 310 will not rise during the illumination process 330 above an initial temperature of the semiconductor substrate 310 before illumination. However, if the temperature does rise, the rise should be less than it otherwise would be in the absence of chilling.

The illumination source may be, e.g. a narrow-spectrum source such as a laser or a broad-spectrum source such as a Xe flash lamp. The illumination may include visible and/or invisible wavelengths. The illumination source provides energy to heat the surface of the semiconductor substrate 310 to about the melting point of the semiconductor, e.g. about 1410° C. for Si. The heating preferably takes place over a short period, e.g. one second or less, to minimize heating of the semiconductor substrate 310. In some embodiments, the heating time is preferably about 100 ms or less, while in other embodiments the heating time is preferably about 10 ms or less.

In one embodiment, illumination is provided by a CO₂ or excimer laser. The laser beam may be optically focused to a power density ranging from about 1 E 5 W/cm² to about 1 E 7 W/cm². Such a beam may be provided, e.g., by a Micropoint Laser system, manufactured by Photonic Industries, St. Charles, Ill. For example a suitably configured laser source is described in the '976 Application.

In summary, a laser with a beam power of, e.g. 1 E-3 W is focused to produce a power density ranging from about 8 E-3 W/μm² to about 1.4 E-2 W/μm² at the semiconductor surface. The exposure time may be adjusted, e.g. between about 1 μs and about ms, to result in the formation of a quenched amorphous semiconductor layer at the exposure site. In another example, a dynamic surface annealing (DSA) system, such as the Applied Vantage Astra system available from Applied Materials, Santa Clara, Calif., USA may also provide short-duration narrow-band illumination. In another embodiment the illumination source includes a broad-spectrum source such as a Xe lamp with focusing optics and/or an optical fiber used to produce a desired spot size.

A focused high-intensity light spot may be rastered across a semiconductor surface to convert an exposed portion of the surface to the amorphous allotrope of the semiconductor. The illumination spots may be narrow-band or broad-band. The conversion throughput may be increased by simultaneously rastering multiple spots over the semiconductor surface. For example, FIG. 4 illustrates an embodiment in which a plurality of illumination spots, e.g. two, rasters across the surface of the semiconductor substrate 310. The time required to illuminate a desired area of the semiconductor substrate 310 is thus reduced by about one half. Of course this principle may be extended to any number of illumination spots within a practical limit. In this way the described method may be scaled up to support a high-throughput manufacturing line.

In another embodiment a broad-spectrum source applies a blanket illumination over the surface of the semiconductor. For example, a flash lamp anneal (FLA) system, such as the Millios system manufactured by Mattson Technology, Inc., Fremont, Calif., USA may be used to provide a short-duration, e.g. 10 ms, broad-spectrum illumination sufficient to melt the semiconductor surface.

In contrast to conventional use of DSA or FLA, the semiconductor substrate 310 may be unheated or chilled so that the surface melt is quenched rather than annealed. Such operation is in marked contrast to a conventional DSA or FLA process, in which recrystallization of the semiconductor surface is typically desired.

The conditions that result in the formation of a quenched amorphous layer of a desired depth generally need to be determined for a given set of conditions. Such conditions may include, e.g. material type, the intensity vs. wavelength distribution of the light used, substrate temperature and the desired conversion depth. Process conditions that result in the desired conversion depth may be determined with the aid of design-of-experiment (DOE) techniques known to those skilled in the pertinent art. See, e.g. George E. P. Box, et al., “Statistics for Experimenters,” John Wiley and Sons (1978).

In some embodiments (not shown) an oxide layer may be deposited or thermally grown on the doped semiconductor layer 315 before it is illuminated. Such an oxide layer may protect the doped semiconductor layer 315 from thermal damage and/or reaction to ambient gases such as oxygen or nitrogen. The oxide layer may be selectively removed at a later process step when its protection is no longer needed.

FIG. 3D illustrates a step in which an electrode layer 340 is formed over the quenched amorphous layer 335. The electrode layer 340 may be formed, e.g. of ITO or other suitable conventional material by a sputter process 345. The thickness of the electrode layer 340 is not limited to any particular value, and may be, e.g. about 100 nm. If an oxide layer was formed over the quenched amorphous layer 335, it is removed prior to the ITO deposition. The electrode layer 340 is electrically conductive and transparent to a wide range of optical wavelengths desirable for photovoltaic power generation. Hence the electrode layer 340 acts as a transparent electrode in the finished PV cell.

FIG. 3E illustrates the PV cell 300 illuminated by, e.g. solar illuminance 350. When illuminated the PV cell 300 produces a voltage potential, with the electrode layer 340 and the substrate 310 acting as terminals of the PV cell 300.

FIGS. 5A-5K illustrate a second embodiment of forming a PV cell. The illustrated process steps form an HIT PV cell 500 using principles described with respect to the PV cell 300. Forming the HIT PV cell 500 begins in FIG. 5A with providing a semiconductor substrate 510. The semiconductor substrate 510 may be as described with respect to the semiconductor substrate 310. In the following description the semiconductor substrate 510 and various semiconductor layers thereover may be described without limitation as being doped or intrinsic silicon, while recognizing the described method may be practiced with other semiconductor types.

In FIG. 5B a p-type polysilicon layer 520 is formed on the semiconductor substrate 510. The p-type polysilicon layer 520 may be formed by a conventional polysilicon CVD process. The source gas may be doped in-situ with a p-type dopant, e.g. boron, to result in the desired doping level. In some embodiments the doping level is about 1 E 19 cm⁻³. The p-type polysilicon layer 520 may be deposited to a thickness ranging from about 20 nm to about 500 nm, with about 100 nm being preferred.

In FIG. 5C, an illumination process 525 illuminates the p-type polysilicon layer 520 with high-intensity light. As described previously, the light may be narrow spectrum, e.g. a laser, or broad spectrum, e.g. a flash lamp. In a preferred embodiment the illumination is performed in an ambient that is substantially free of oxygen, e.g. a vacuum. The illumination at least partially melts the p-type polysilicon layer 520. The melted layer 520 rapidly cools after the illumination process 525 ends, and is thereby quenched. The p-type polysilicon layer 520 is thus at least partially converted to quenched amorphous silicon in a p-type amorphous silicon layer 530. The conversion may include a chilling process 527 that chills the semiconductor substrate 510 as described previously with respect to the semiconductor substrate 310. In an alternate embodiment the p-type amorphous silicon layer 530 may be formed by illuminating the substrate 510 to form a quenched amorphous layer.

The configuration illustrated by FIG. 5C, e.g. the amorphous silicon layer 530 located on the crystalline silicon semiconductor substrate 510, may be formed by the entity performing the subsequent processing steps of the cell 500, or may be performed by a separate entity and provided for subsequent processing. Similarly, the configuration illustrated by FIG. 3C may be provided by a separate entity from the entity performing later processing steps of the cell 300. Thus, for example, a semiconductor wafer manufacturer may produce for commercial sale a crystalline semiconductor wafer with an overlying intrinsic or doped amorphous layer of the semiconductor. The amorphous layer may optionally cover substantially an entirety of a top surface, e.g. a polished side, of the semiconductor wafer.

In FIG. 5D an intrinsic polysilicon layer 535 is formed on the p-type amorphous silicon layer 530. Again, a conventional CVD process may be used, but without a dopant gas. The intrinsic polysilicon layer 535 may be deposited with a thickness ranging from about 20 nm to about 1000 nm, with about 400 nm being preferred.

In FIG. 5E, an illumination process 540 heats the intrinsic polysilicon layer 535 with high-intensity light. The illumination process 540 may be as described with respect to the illumination process 525 with suitable modifications to take into account, e.g. differences in layer thickness. The illumination process 540 at least partially melts the intrinsic polysilicon layer 535, thereby forming an, intrinsic quenched amorphous layer 545 when cooled. The conversion may include a chilling process 547 that chills the semiconductor substrate 510 as described previously with respect to the semiconductor substrate 310.

In FIG. 5F an n-type polysilicon layer 550 is formed on the intrinsic amorphous layer 545. Again, a conventional CVD process may be used, with an n-type dopant gas such as phosphine. The n-type polysilicon layer 550 may be deposited to a thickness ranging from about 20 nm to about 500 nm, with about 100 nm being preferred, and a dopant concentration ranging from about 1 E 17 cm⁻³ to about 1 E 19 cm⁻³, with about 1 E 18 cm⁻³ being preferred.

In FIG. 5G an intrinsic polysilicon layer 555 is formed on the n-type polysilicon layer 550. The intrinsic polysilicon layer 555 may be deposited to a thickness ranging from about 20 nm to about 1000 nm, with about 400 nm being preferred.

In FIG. 5H, an illumination process 560 heats the intrinsic polysilicon layer 555 with high-intensity light. The illumination process 560 may be as described with respect to the illumination process 525 with suitable modifications to take into account, e.g. differences in layer thickness. The illumination at least partially melts the intrinsic polysilicon layer 555, which forms a quenched amorphous intrinsic layer 565 when cooled. The conversion may include a chilling process 567 that chills the semiconductor substrate 510 as described previously with respect to the semiconductor substrate 310. The layers 530, 545, 550 form a PIN diode located between the intrinsic quenched amorphous layer 565 and the semiconductor substrate 510.

In FIG. 5I an n-type polysilicon layer 570 is formed on the quenched amorphous intrinsic layer 565. Again, the polysilicon layer 570 may be doped with phosphorous. The n-type polysilicon layer 570 may be deposited to a thickness ranging from about 20 nm to about 500 nm, with about 100 nm being preferred, and a dopant concentration ranging from about 1 E 18 cm⁻³ to about 1 E 21 cm⁻³, with about 5 E 19 cm⁻³ being preferred.

In FIG. 5J, an illumination process 575 heats the n-type polysilicon layer 570 with high-intensity light as described previously with respect to the illumination process 525. Suitable modifications may be made to take into account, e.g. differences in layer thickness. The illumination at least partially melts the n-type polysilicon layer 570, which forms a quenched amorphous n-type layer 580 when cooled. The conversion may include a chilling process 582 that chills the semiconductor substrate 510 as described previously with respect to the semiconductor substrate 310.

In FIG. 5K, an electrode layer 585, e.g. ITO, is conventionally formed on the amorphous n-type layer 580. The electrode layer 585 may have a thickness of about 100 nm, and is at least partially transparent to light. When illuminated by light, e.g. solar illuminance, the PV cell 500 produces a voltage potential, with the electrode layer 585 and the semiconductor substrate 510 acting as terminals of the PV cell 500.

In the preceding method, the layers 530, 545, 550, 565 580 are derived from CVD polysilicon layers. As such, these layers may include a similar hydrogen concentration as a conventionally formed polysilicon layer. However, manufacturing the HIT PV cell 500 is expected to benefit from the relative ease of producing the amorphous layers 530, 545, 565, 580. Furthermore, the performance of the HIT PV cell 500 may benefit from highly uniform thin quenched amorphous semiconductor layers and a high quality interface between adjacent pairs of layers expected to result from the disclosed methods.

Those skilled in the art to which this application relates will appreciate that other and further additions, deletions, substitutions and modifications may be made to the described embodiments.

What is claimed is:

1. A method of forming a photovoltaic cell, comprising:
providing a substrate;
forming a crystalline semiconductor layer over said substrate; and
heating said crystalline semiconductor layer above a melting temperature of said semiconductor thereby converting at least a portion of said crystalline semiconductor layer to a quenched amorphous semiconductor layer.

2. The method as recited in claim 1, wherein said heating comprises illuminating said crystalline semiconductor layer with laser light.

3. The method as recited in claim 1, wherein said heating includes rastering a plurality of illumination spots across a surface of said crystalline semiconductor layer.

4. The method as recited in claim 1, wherein said heating comprises illuminating said crystalline semiconductor layer with a high-intensity flash lamp.

5. The method as recited in claim 1, wherein said converting further comprises chilling said substrate while heating said crystalline semiconductor layer.

6. The method as recited in claim 1, wherein said quenched amorphous semiconductor layer is a doped layer, and further comprising forming on said doped layer an intrinsic polycrystalline layer, and heating said intrinsic polycrystalline layer to form a quenched intrinsic amorphous layer.

7. The method as recited in claim 6, wherein said quenched amorphous semiconductor layer is an intrinsic layer, and further comprising forming on said intrinsic layer a doped polycrystalline semiconductor layer.

8. The method as recited in claim 7, further comprising heating said doped polycrystalline semiconductor layer thereby converting a portion thereof to a doped quenched amorphous semiconductor layer.

9. The method as recited in claim 7, further comprising forming on said doped polycrystalline layer an intrinsic polycrystalline layer, and heating said intrinsic polycrystalline layer to form an intrinsic quenched amorphous layer.

10. The method as recited in claim 1, wherein said substrate is a crystalline semiconductor layer.

11. The method as recited in claim 10, further comprising illuminating said substrate thereby forming a quenched amorphous portion of said substrate.

12. A photovoltaic cell, comprising:
a substrate;
an amorphous semiconductor layer located over said substrate, said amorphous semiconductor layer being formed by heating a surface of a crystalline semiconductor layer above a melting point of said semiconductor, thereby converting at least a portion of said crystalline semiconductor layer to an amorphous allotrope of said semiconductor.

13. The photovoltaic cell as recited in claim 12, wherein said amorphous semiconductor layer is an intrinsic layer, and further comprising a p-type amorphous semiconductor layer located between said substrate and said intrinsic layer.

14. The photovoltaic cell as recited in claim 12, wherein said amorphous semiconductor layer is an intrinsic layer, and further comprising a p-type amorphous semiconductor layer and an n-type polycrystalline layer located between said substrate and said intrinsic layer.

15. The photovoltaic cell as recited in claim 12, wherein said amorphous semiconductor layer is an n-type layer, and further comprising layers forming a PIN diode located between said amorphous semiconductor layer and said substrate.

16. The photovoltaic cell as recited in claim 12, wherein said amorphous semiconductor layer is a p-type layer, and further comprising a first intrinsic amorphous layer located on said p-type layer, an n-type polycrystalline layer on said first intrinsic layer, a second intrinsic amorphous layer on said polycrystalline layer, and an n-type amorphous semiconductor layer on said second intrinsic amorphous layer.

17. The photovoltaic cell as recited in claim 12 wherein said amorphous layers is formed by first depositing a polycrystalline semiconductor layer and then illuminating said polycrystalline semiconductor layer, thereby converting a portion thereof to an amorphous allotrope.

18. The photovoltaic cell as recited in claim 17, wherein said illuminating includes illuminating with a high-intensity flash lamp.

19. The photovoltaic cell as recited in claim 12, wherein said converting further comprises chilling said substrate while illuminating said crystalline semiconductor layer.

20. The photovoltaic cell as recited in claim 12, wherein said substrate is a crystalline semiconductor layer.

21. A photovoltaic cell, comprising:
a substrate;
a semiconductor material layer having a first conductivity type; and
a quenched amorphous layer of said semiconductor material located over said substrate, said quenched amorphous layer having a second different conductivity type,
wherein said quenched amorphous layer comprises no more than about 0.1 at. % hydrogen.

22. The photovoltaic cell of claim 21, wherein said quenched amorphous. layer is doped.

23. The photovoltaic cell as recited in claim 21, wherein said substrate is a crystalline semiconductor and said quenched amorphous layer is formed by heating a surface of said substrate above a melting point of said semiconductor and quenching a melted semiconductor layer.

24. A semiconductor wafer, comprising:
a crystalline semiconductor substrate;
an amorphous semiconductor layer located over said substrate, said amorphous semiconductor layer being formed by heating a surface of a crystalline semiconductor layer above a melting point of said semiconductor, thereby converting at least a portion of said crystalline semiconductor layer to an amorphous allotrope of said semiconductor.

25. The semiconductor wafer as recited in claim 24, wherein said amorphous semiconductor layer is formed from said crystalline semiconductor substrate.

26. The semiconductor wafer as recited in claim 24, wherein said amorphous semiconductor layer covers substantially an entirety of a top surface of said crystalline semiconductor substrate.

27. The semiconductor wafer as recited in claim 24, wherein said amorphous semiconductor layer is an intrinsic semiconductor layer.
